(19) United States
(12) Patent Application Publication
(10) Pub. No.: US 2025/0273602 A1
(43) Pub. Date: Aug. 28, 2025

(54) MODULE AND METHOD FOR MANUFACTURING MODULE

(71) Applicant: Murata Manufacturing Co., Ltd., Nagaokakyo-shi (JP)

(72) Inventor: Mamoru NAKASHIMA, Nagaokakyo-shi (JP)

(21) Appl. No.: 19/206,700

(22) Filed: May 13, 2025

Related U.S. Application Data
(63) Continuation of application No. PCT/JP2023/035628, filed on Sep. 29, 2023.

(30) Foreign Application Priority Data
Nov. 15, 2022 (JP) 2022-182610

(51) Int. Cl. H01L 23/58; H01L 23/31; H01L 25/18

(52) U.S. Cl. CPC H01L 23/585; H01L 23/3107; H01L 25/18

(57) ABSTRACT

A module, including: a sealed body including a circuit board and an electronic component each sealed with a sealing resin, wherein a conductor is exposed from a part of a surface of the sealed body; and a rewiring layer disposed on a surface of the sealed body and including an insulating layer and a rewiring conductor connected to the conductor, wherein the rewiring conductor includes: a connecting conductor disposed in the insulating layer and connected to the conductor; and an input/output electrode disposed on a surface of the insulating layer on a side opposite to a side facing the sealed body and connected to the connecting conductor, and the rewiring conductor and the insulating layer include first pores and second pores, respectively, each of the first pores having a smaller average diameter than each of the second pores in the insulating layer.

### CROSS REFERENCE TO RELATED APPLICATION

This is a continuation of International Application No. PCT/JP2023/035628 filed on Sep. 29, 2023 which claims priority from Japanese Patent Application No. 2022-182610 filed on Nov. 15, 2022. The contents of these applications are incorporated herein by reference in their entireties.

### BACKGROUND OF THE DISCLOSURE

### Field of the Disclosure

The present disclosure relates to modules and methods for producing modules.

### Description of the Related Art

JP 3632684 B discloses a porous insulating layer that is formed using, as an insulating material, a resin containing a styrene group-containing compound as a cross-linking component. The literature describes that use of the porous insulating layer enables production of semiconductor elements and semiconductor packages each having a low dielectric constant, a low dielectric loss, low moisture absorption, and high heat resistance.

### BRIEF SUMMARY OF THE DISCLOSURE

Modules with a package-on-package (POP) structure have been developed. A POP structure, which is constructed by stacking electronic components including packaged components, requires a small mounting area and can achieve high functionality.

In order to allow such modules to have a fan-out structure, a structure with a rewiring layer is conceivable.

The present inventors considered the use of the porous insulating layer described in JP 3632684 B as a rewiring layer.

However, although JP 3632684 B describes that an insulating layer with a porous structure can have a low dielectric constant, the size of pores in the insulating layer and the relationship regarding pores between the insulating layer and a wiring conductor are not considered. The study of the present inventors revealed that degradation due to thermal cycling has room for improvement.

The present disclosure was made to solve the above issue and aims to provide a module that includes a rewiring layer including a rewiring conductor and can prevent or reduce degradation due to thermal cycling, and a method for producing the module.

A module of the present disclosure includes: a sealed body including a circuit board and an electronic component each sealed with a sealing resin, wherein a conductor is exposed from a part of a surface of the sealed body; and a rewiring layer disposed on the surface of the sealed body and including an insulating layer and a rewiring conductor connected to the conductor, wherein the rewiring conductor includes: a connecting conductor disposed in the insulating layer and connected to the conductor; and an input/output electrode disposed on a surface of the insulating layer on a side opposite to a side facing the sealed body and connected to the connecting conductor, and the rewiring conductor and the insulating layer include first pores and second pores, respectively, each of the first pores having a smaller average diameter than each of the second pores.

A method for producing the module of the present disclosure includes forming the rewiring conductor by screen printing using a first paste containing a conductive filler having an average particle size of 0.1 μm or more and 1.0 μm or less, a resin, and a solvent; and forming the insulating layer by screen printing using a second paste containing a filler having an average particle size of more than 1.0 μm and 10.0 μm or less, a resin, and a solvent.

The present disclosure can provide a module that includes a rewiring layer including a rewiring conductor and can prevent or reduce degradation due to thermal cycling, and a method for producing the module.

### BRIEF DESCRIPTION OF THE SEVERAL VIEWS OF THE DRAWINGS

FIG. 1 is a schematic cross-sectional view of an example of a module of the present disclosure (first embodiment).

FIG. 2 is an enlarged view of a part surrounded by a dashed line in FIG. 1.

FIG. 3 is a schematic view of an example of pores in a rewiring conductor.

FIG. 4 is a schematic cross-sectional view of an example of an electronic component module of the present disclosure (first embodiment) during production, showing mounting of a first electronic component and a third electronic component.

FIG. 5 is a schematic cross-sectional view of an example of the electronic component module of the present disclosure (first embodiment) during production, showing first sealing with a resin.

FIG. 6 is a schematic cross-sectional view of an example of the electronic component module of the present disclosure (first embodiment) during production, showing forming of an in-plane wiring.

FIG. 7 is a schematic cross-sectional view of an example of the electronic component module of the present disclosure (first embodiment) during production, showing forming of a via.

FIG. 8 is a schematic cross-sectional view of an example of the electronic component module of the present disclosure (first embodiment) during production, showing forming of an insulating layer.

FIG. 9 is a schematic cross-sectional view of an example of the electronic component module of the present disclosure (first embodiment) during production, showing forming of an input/output electrode.

FIG. 10 is a schematic cross-sectional view of an example of the electronic component module of the present disclosure (first embodiment) during production, showing mounting of a second electronic component and a fourth electronic component.

FIG. 11 is a schematic cross-sectional view of an example of the electronic component module of the present disclosure (first embodiment) during production, showing second sealing with a resin.

FIG. 12 is a schematic cross-sectional view of an example of a rewiring layer in the present disclosure (second embodiment).

FIG. 13 is a schematic cross-sectional view of an example of a rewiring layer in the present disclosure (third embodiment).

### DETAILED DESCRIPTION OF THE DISCLOSURE

The module of the present disclosure is described below.

The present disclosure is not limited to the following preferred embodiments, and may be suitably modified without departing from the gist of the present disclosure. Combinations of two or more preferred features described in the following preferred embodiments are also within the scope of the present disclosure.

The module of the present disclosure includes: a sealed body including a circuit board and an electronic component each sealed with a sealing resin, wherein a conductor is exposed from a part of a surface of the sealed body; and a rewiring layer disposed on the surface of the sealed body and including an insulating layer and a rewiring conductor connected to the conductor, wherein the rewiring conductor includes: a connecting conductor disposed in the insulating layer and connected to the conductor; and an input/output electrode disposed on a surface of the insulating layer on a side opposite to a side facing the sealed body and connected to the connecting conductor, and the rewiring conductor and the insulating layer include first pores and second pores, respectively, each of the first pores having a smaller average diameter than each of the second pores. This module includes a rewiring layer including a rewiring conductor and therefore can prevent or reduce degradation due to thermal cycling.

The above-described effect is achieved presumably because the pores in the insulating layer reduce the thermal expansion of the insulating layer, while the insulating layer and the rewiring conductor have a higher flexibility due to the pores therein. Further, when the pores in the insulating layer are smaller than the pores in the rewiring conductor, the thermal expansion coefficient of the insulating layer, which has a large thermal expansion coefficient, decreases, and the thermal expansion coefficient of the rewiring conductor, which has a small thermal expansion coefficient, fluctuates little. Thus, the difference in the thermal expansion coefficient between the insulating layer and the rewiring conductor is reduced, thereby preventing or suppressing separation between the insulating layer and the rewiring conductor. Consequently, degradation due to thermal cycling can be presumably prevented or suppressed.

### First Embodiment

An electronic component module according to a first embodiment mainly features that pores in the rewiring conductor have a smaller average diameter than pores in the insulating layer.

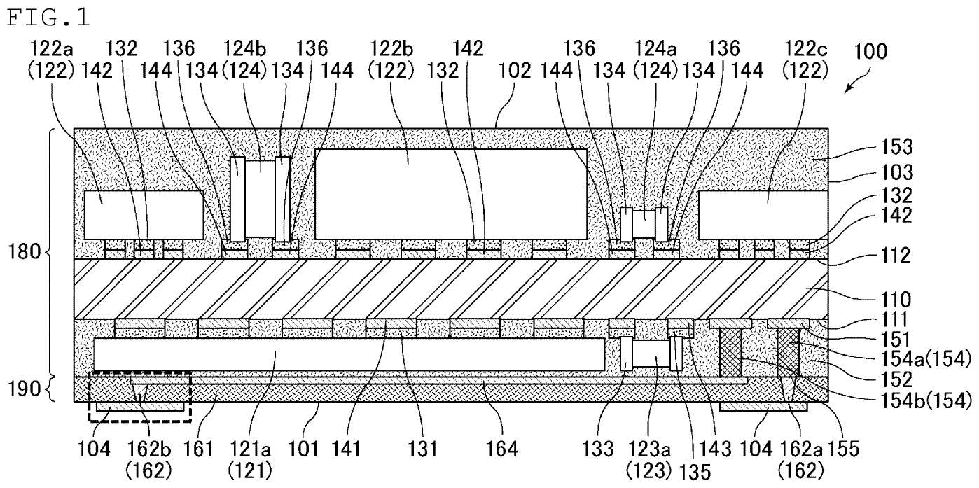

FIG. 1 is a schematic cross-sectional view of an example of a module (electronic component module) of the present disclosure (first embodiment).

An electronic component module 100 shown in FIG. 1 is a module having a substantially rectangular cuboidal shape and including a mounting surface 101, a top surface 102 opposite to the mounting surface 101, and four side surfaces 103 interconnecting the mounting surface 101 and the top surface 102. The mounting surface 101 is provided with multiple input/output electrodes (I/O electrodes) 104 to be connected to other electronic components and boards (e.g., a motherboard).

The electronic component module 100 shown in FIG. 1 includes: a sealed body 180 that includes a low-temperature sintered ceramic substrate (hereinafter, referred to as LTCC substrate) 110 and electronic components (a first electronic component 121, a second electronic component 122, a third electronic component 123, and a fourth electronic component 124) each sealed with a sealing resin layer 152 or 153 and has a surface including parts where columnar electrodes 154, which are conductors, are exposed; and a rewiring layer 190 that is disposed on the surface of the sealed body 180 including the parts where the columnar electrodes 154 are exposed and includes an insulating layer 161 and rewiring conductors (such as input/output electrodes 104, an in-plane wiring 164, and vias 162) connected to the columnar electrodes 154, which are conductors. As described above, the electronic component module 100 shown in FIG. 1 includes the sealed body 180 and the rewiring layer 190. Hereinbelow, the sealed body 180 is mainly described first, and then the rewiring layer 190 is described.

Here, the sealed body 180 is an example of the “sealed body” in the module of the present disclosure, and the rewiring layer 190 is an example of the “rewiring layer” in the module of the present disclosure. The columnar electrodes 154 are examples of the “conductor” in the module of the present disclosure. Further, the input/output electrodes 104, the in-plane wiring 164, and the vias 162 are examples of the “rewiring conductor” in the module of the present disclosure. Of these, the in-plane wiring 164 and the vias 162 are examples of the “connecting conductor” in the module of the present disclosure, and the input/output electrodes 104 are examples of the “input/output electrode” in the module of the present disclosure. The insulating layer 161 is an example of the “insulating layer” in the module of the present disclosure. The LTCC substrate 110 is an example of the “circuit board” in the module of the present disclosure. The first electronic component 121, the second electronic component 122, the third electronic component 123, and the fourth electronic component 124 are examples of the “electronic component” in the module of the present disclosure. The sealing resin layers 152 and 153 are examples of the “sealing resin” in the module of the present disclosure.

The electronic component module 100 is an electronic component module with components mounted on both surfaces of a board, and internally includes, as a circuit board, the LTCC substrate 110 including a first main surface 111 adjacent to the mounting surface 101 and a second main surface 112 adjacent to the top surface 102, the first electronic component 121 mounted on the first main surface 111, and a plurality of the second electronic components 122 mounted on the second main surface 112.

The first electronic component 121 includes a mounting surface provided with multiple Cu pillar bumps 131 as external terminals.

Each second electronic component 122 also includes a mounting surface provided with multiple Cu pillar bumps 132 as external terminals.

The LTCC substrate 110 is a multilayer ceramic substrate in which an insulating layer (at least one insulating layer may include a via) and a conductor layer including wirings and electrodes are laminated together. Examples of materials of the conductor layer and vias include metal materials such as silver or copper. Examples of insulating materials of the insulating layer include low-temperature sintered ceramic materials. The low-temperature sintered ceramic materials are a type of ceramic material that can be sintered simultaneously with silver and copper used as metal materials at a sintering temperature of 1000° C. or lower. Examples include those containing SiO₂—BaO—Al₂O₃—MnO-based glass ceramic or SiO₂—BaO—Al₂O₃—MnO—TiO₂—MgO—ZrO₂-based glass ceramic.

The first main surface 111 of the LTCC substrate 110 is provided with multiple first electrodes (mounting pads) 141 in one-to-one correspondence with the Cu pillar bumps 131 (external terminals) of the first electronic component 121. The first electronic component 121 is flip-chip mounted on the first main surface 111 as a result of connection of each Cu pillar bump 131 to its corresponding first electrode 141.

Each first electrode 141 is connected to its corresponding wiring (not shown) of the LTCC substrate 110.

The first electronic component 121 is not limited, and it is preferably an electronic component including a mounting surface provided with multiple external terminals. Here, a surface mount type electronic component including the multiple Cu pillar bumps 131 as external terminals is mounted.

The first electronic component 121 is preferably an integrated circuit (IC). Here, a silicon on insulator (SOI) 121a is mounted. Alternatively, the first electronic component 121 may be, for example, a GaAs IC, a Si IC, a SiC IC, or the like.

In the case where the electronic component module 100 is an electronic component module with components mounted on both surfaces, it suffices as long as at least one first electronic component 121 is mounted on the first main surface 111 of the LTCC substrate 110. Multiple first electronic components 121 may be mounted.

The second main surface 112 of the LTCC substrate 110 is provided with multiple second electrodes (mounting pads) 142 in one-to-one correspondence with the Cu pillar bumps 132 (external terminals) of each second electronic component 122. Each second electronic component 122 is flip-chip mounted on the second main surface 112 as a result of connection of each Cu pillar bump 132 to its corresponding second electrode 142.

Each second electrode 142 is connected to its corresponding wiring (not shown) of the LTCC substrate 110.

The second electronic components 122 are not limited and are each preferably an electronic component including a mounting surface provided with multiple external terminals. Here, a surface mount type electronic component including the multiple Cu pillar bumps 132 as external terminals is mounted.

The second electronic components 122 are preferably ICs. Here, a heterojunction bipolar transistor (HBT) IC 122a, a surface acoustic wave (SAW) filter 122b, and a GaAs IC 122c are mounted.

A third electronic component 123 is mounted on the first main surface 111 of the LTCC substrate 110. The third electronic component 123 includes a mounting surface, a top surface opposite to the mounting surface, and paired external electrodes 133 as multiple external electrodes, instead of Cu pillar bumps (external terminals).

The paired external electrodes 133 are connected to the LTCC substrate 110. Here, each external electrode 133 is formed on a total of five surfaces, extending from the mounting surface to the top surface through the three side surfaces of the third electronic component 123.

More specifically, the first main surface 111 is provided with multiple third electrodes 143. The third electrodes 143 are in one-to-one correspondence with the paired external electrodes 133 of the third electronic component 123. The third electronic component 123 is mounted on the first main surface 111 as a result of connection of each external electrode 133 to its corresponding third electrode 143. Each external electrode 133 is connected to its corresponding third electrode 143 with, for example, solder 135. The third electronic component 123 is not limited. Here, for example, a chip capacitor 123a is mounted.

Each third electrode 143 is connected to its corresponding wiring (not shown) of the LTCC substrate 110.

FIG. 1 shows a case where only one third electronic component 123 is mounted, but multiple third electronic components 123 may be similarly mounted on the first main surface 111 of the LTCC substrate 110.

Further, multiple fourth electronic components 124 each including paired external electrodes 134 instead of Cu pillar bumps (external terminals) are mounted on the second main surface 112 of the LTCC substrate 110.

More specifically, the second main surface 112 is provided with multiple fourth electrodes 144. The fourth electrodes 144 are in one-to-one correspondence with the paired external electrodes 134 of each fourth electronic component 124. Each fourth electronic component 124 is mounted on the second main surface 112 as a result of connection of each external electrode 134 to its corresponding fourth electrode 144. Each external electrode 134 is connected to its corresponding fourth electrode 144 with, for example, solder 136. The fourth electronic components 124 are not limited. Here, for example, a chip capacitor 124a and a chip inductor 124b are mounted.

Each fourth electrode 144 is connected to its corresponding wiring (not shown) of the LTCC substrate 110.

A sealing resin layer 153 covering the second electronic components 122 and the fourth electronic components 124 are provided on the second main surface 112 of the LTCC substrate 110.

In the case where the electronic component module 100 is an electronic component module with components mounted on both surfaces, it suffices as long as at least one second electronic component 122 is mounted on the second main surface 112 of the LTCC substrate 110. Electronic components other than the second electronic components 122, for example, at least one of the fourth electronic components 124, may be omitted.

The electronic component module 100 includes multiple electrodes for input/output 151 on the first main surface 111 of the LTCC substrate 110, multiple columnar electrodes 154 connected to the multiple electrodes for input/output 151, and a sealing resin layer 152 covering the first main surface 111 of the LTCC substrate 110.

The columnar electrodes 154 are in one-to-one correspondence with the electrodes for input/output 151. The sealing resin layer 152 covers the first main surface 111 of the LTCC substrate 110, the first electronic component 121, and the third electronic component 123 and also fills the space around the columnar electrodes 154.

Each columnar electrode 154 has an end surface 155 exposed from the sealing resin layer 152.

The electronic component module 100 includes the rewiring layer 190 on the surface of the sealed body 180 such that the rewiring layer 190 covers the sealing resin layer 152. The rewiring layer 190 includes the via 162a connected to the first columnar electrode 154a, the input/output electrode 104 connected to the via 162a, the in-plane wiring 164 connected to the second columnar electrode 154b, the via 162b connected to the in-plane wiring 164, and the input/output electrode 104 connected to the via 162b. The rewiring layer 190 includes the insulating layer 161, and the vias 162a and 162b penetrate the insulating layer 161.

The multiple input/output electrodes 104 are mounted on a surface of the insulating layer 161 on the side opposite to the side facing the sealed body 180 and connected to the multiple columnar electrodes 154 via the respective multiple vias 162 and the in-plane wiring 164.

The via 162a connected to the first columnar electrode 154a extends in the insulating layer 161 in the thickness direction to directly contact the input/output electrode 104 which is mounted on the surface of the insulating layer 161 on the side opposite to the side facing the sealed body 180. Here, one end surface of the via 162a is connected to the end surface 155, which is exposed from the sealing resin layer 152, of the first columnar electrode 154a, and the other end surface of the via 162a is connected to the input/output electrode 104.

The in-plane wiring 164 connected to the second columnar electrode 154b extends in the insulating layer 161 in the surface direction, so that the input/output electrodes can be mounted at desired positions. The in-plane wiring 164 extends from the boundary with the second columnar electrode 154b in the insulating layer 161 in the surface direction to contact the via 162b. Further, the via 162b extends in the insulating layer 161 in the thickness direction to directly contact the input/output electrode 104 mounted on the surface of the insulating layer 161 on the side opposite to the side facing the sealed body 180.

The thickness of the in-plane wiring 164 is not limited, and it is preferably 3.0 μm or more and 20.0 μm or less, more preferably 5.0 μm or more and 15.0 μm or less.

Preferably, the insulating layer 161 is an insulating layer made of resin, i.e., a resin insulating layer, or may be one (planarization layer) that forms a substantially flat surface by absorbing irregularities of the base.

The insulating layer 161, excluding portions where the vias 162 and the in-plane wiring 164 are formed, covers its underneath component, i.e., the sealed body 180.

In other words, the insulating layer 161 is partly in contact with the surface of the sealed body 180.

The insulating layer 161 and the rewiring conductors including the connecting conductors such as the vias 162 and the in-plane wiring 164 in the insulating layer 161 and the input/output electrodes 104 mounted on the insulating layer 161 function as rewiring layers. Preferably, the insulating layer 161 is in contact with the rewiring conductors including the connecting conductors such as the vias 162 and the in-plane wiring 164 in the insulating layer 161 and the input/output electrodes 104 mounted on the insulating layer 161.

Here, the insulating layer 161 may be in contact with the surface of the first electronic component 121 or the surface of the third electronic component 123.

The thickness of the insulating layer 161 is not limited. For example, the thickness may be 5 μm or more and 50 μm or less, 10 μm or more and 40 μm or less, or 15 μm or more and 30 μm or less. The thickness of the insulating layer 161 is usually the same as the thickness of the rewiring layer 190. Herein, the thickness of the insulating layer 161 means the largest thickness of the insulating layer 161.

The rewiring conductors such as the in-plane wiring 164, the vias 162, and the input/output electrodes 104 each preferably contain a conductive filler and a resin. Such rewiring conductors can better exhibit a function as a wiring while more suitably preventing or suppressing degradation due to thermal cycling. The rewiring conductors are preferably dry films.

Examples of the conductive filler include metal fillers such as silver filler, copper filler, and nickel filler. The conductive filler is preferably silver filler among these.

The conductive filler may have any particle shape, for example, a plate, flaky, or spherical particle shape. The conductive filler preferably has a spherical particle shape.

The conductive filler preferably has an average particle size of 0.1 μm or more and 1.0 μm or less, more preferably 0.2 μm or more and 0.8 μm or less. This makes it possible to further prevent or suppress degradation due to thermal cycling. The effect can be achieved probably because the conductive filler can further reduce the thermal expansion of the insulating layer while further improving the flexibility of the rewiring conductors.

Herein, the average particle size of the conductive filler or other fillers is calculated by the following method.

A cross-section in the thickness direction of the module is polished. The areas of the particles of the filler appearing on the surface of the cross-section are measured with an electron microscope to calculate circle-equivalent diameters. The circle-equivalent diameters of at least 100 particles of the filler are calculated, and the number average of the diameters is defined as an average particle size.

Meanwhile, the average particle size of the conductive filler or other fillers contained in the paste can usually be measured with a laser diffraction particle size distribution analyzer.

The resin in the rewiring conductors may be any of thermosetting resins and thermoplastic resins. Examples of the resin include phenol resin, formaldehyde resin, melamine resin, epoxy resin, acrylic resin, polyester resin, polyamide resin, polyamide imide resin, polyphenylene sulfide resin, polyether resin, polyimide resin, and polyether ether ketone resin. The resin is preferably polyester resin among these.

The amount of the conductive filler in each rewiring conductor relative to the amount of the rewiring conductor as a whole is preferably 85 wt % or more and 99 wt % or less, more preferably 87 wt % or more and 97 wt % or less. The amount of the resin in each rewiring conductor relative to the amount of the rewiring conductor as a whole is preferably 1 wt % or more and 10 wt % or less, more preferably 3 wt % or more and 8 wt % or less. The total amount of the conductive filler and the resin in each rewiring conductor relative to the amount of the rewiring conductor as a whole is preferably 86 wt % or more, more preferably 93 wt % or more, and may be 100 wt %.

The insulating layer 161 preferably contains a filler and a resin. Preferably, the filler in the insulating layer is not a conductive filler and is also preferably different from the conductive filler in the rewiring conductors.

Examples of the filler include alumina, silica, silicon nitride, and aluminum hydroxide. The filler is preferably silica among these.

The filler may have any particle shape, for example, a plate, flaky, or spherical particle shape. The filler preferably has a spherical particle shape.

The filler preferably has an average particle size of more than 1.0 μm and 10.0 μm or less, more preferably more than 1.0 μm and 8.0 μm or less.

The resin constituting the insulating layer may be any of thermosetting resins and thermoplastic resins. Examples of the resin include epoxy resin, acrylic resin, phenol resin, formaldehyde resin, melamine resin, aromatic polyester resin, polyamide resin, polyphenylene sulfide resin, polyether resin, polyimide resin, polyamide imide resin, and polyether ether ketone resin. The resin is preferably epoxy resin, polyimide resin, or polyamide imide resin among these.

The amount of the filler in the insulating layer relative to the amount of the insulating layer as a whole is preferably 15 wt % or more and 40 wt % or less, more preferably 20 wt % or more and 35 wt % or less. The amount of the resin in the insulating layer relative to the amount of the insulating layer as a whole is preferably 45 wt % or more and 75 wt % or less, more preferably 50 wt % or more and 70 wt % or less. The total amount of the filler and the resin in the insulating layer relative to the amount of the insulating layer as a whole is preferably 65 wt % or more, more preferably 75 wt % or more, and may be 100 wt %.

The electrodes such as the first electrodes 141 on the first main surface 111 of the LTCC substrate 110 and the electrodes such as the second electrodes 142 on the second main surface 112 of the LTCC substrate 110 are formed by firing together with a low-temperature sintered ceramic material. The electrodes such as the input/output electrodes 104 on the insulating layer 161 are formed after the firing.

The input/output electrodes 104 are in one-to-one correspondence with the columnar electrodes 154. As described above, the columnar electrodes 154 are in one-to-one correspondence with the electrodes for input/output 151. In other words, the input/output electrodes 104 are also in one-to-one correspondence with the electrodes for input/output 151.

Each input/output electrode 104 is connected to its corresponding electrode for input/output 151 as a result of connection to its corresponding columnar electrode 154 through the via 162 and the in-plane wiring 164 in the insulating layer 161.

Usually, one via 162 is provided to each pair of the input/output electrode 104 and the columnar electrode 154, but multiple vias may be provided to each pair.

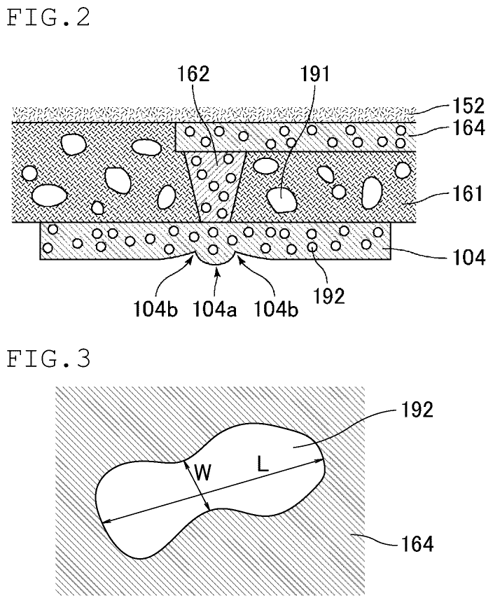

FIG. 2 is an enlarged view of a part surrounded by a dashed line in FIG. 1.

As shown in FIG. 2, pores 192 in the rewiring conductors such as the in-plane wiring 164, the vias 162, and the input/output electrodes 104 each have a smaller average diameter than pores 191 in the insulating layer 161.

Herein, the average diameter of the pores in the insulating layer and the average dimeter of the pores in each rewiring conductor can be calculated by the following method.

A cross-section in the thickness direction of the module is polished. The areas of pores appearing on the surface of the cross-section are measured with an electron microscope to calculate circle-equivalent diameters. The circle-equivalent diameters of at least 100 pores are calculated, and the number average of the diameters is defined as an average diameter.

In the module of the present disclosure, pores in the rewiring conductor have a smaller average diameter than pores in the insulating layer. The difference in the average pore diameter between the rewiring conductor and the insulating layer (the average diameter of the pores in the insulating layer—the average diameter of the pores in the rewiring conductor) is preferably 0.1 μm or more, more preferably 0.3 μm or more, still more preferably 0.5 μm or more. The upper limit is not limited, and it is preferably 5.0 μm or less, more preferably 3.0 μm or less.

In the case of multiple rewiring conductors, it suffices as long as at least one rewiring conductor satisfies the above-described relationship regarding the pores. Preferably, all the rewiring conductors satisfy the relationship regarding the pores. Preferably, at least the connecting conductors among the rewiring conductors satisfy the relationship regarding the pores. More preferably, at least the in-plane wiring among the rewiring conductors satisfies the relationship regarding the pores.

Likewise, in the case of multiple insulating layers, it suffices as long as at least one insulating layer satisfies the above-described relationship regarding the pores. Preferably, all insulating layers satisfy the relationship regarding the pores. Preferably, at least an insulating layer connected to the connecting conductors among insulating layers satisfies the relationship regarding the pores. More preferably, at least an insulating layer connected to the in-plane wiring among insulating layers satisfies the relationship regarding the pores.

The pores in the insulating layer preferably have an average diameter of 0.5 μm or more, more preferably 0.7 μm or more, still more preferably 0.8 μm or more. The upper limit is not limited, and it is preferably 10.0 μm or less, more preferably 5.0 μm or less.

The number of the pores in the insulating layer is preferably 50000/mm² or more and 300000/mm² or less, more preferably 100000/mm² or more and 250000/mm² or less

The pores in each rewiring conductor preferably have an average diameter of 0.8 μm or less, more preferably 0.6 μm or less, still more preferably 0.4 μm or less. The lower limit is not limited, and it is preferably 0.05 μm or more, more preferably 0.1 μm or more.

The number of the pores in each rewiring conductor is preferably 4000000/mm² or more and 14000000/mm² or less, more preferably 6000000/mm² or more and 12000000/mm² or less.

In the present disclosure, the pores in the insulating layer between the in-plane wiring and the input/output electrode may be through or not through, preferably not through, from the in-plane wiring side to the input/output electrode side.

In FIG. 2, the pores 191 in the insulating layer 161 between the in-plane wiring 164 and the input/output electrode 104 are not through from the in-plane wiring 164 side to the input/output electrode 104 side. As described above, preferably, the connecting conductor includes an in-plane wiring extending in the insulating layer in the surface direction, and the pores in the insulating layer between the in-plane wiring and the input/output electrode are not through from the in-plane wiring side to the input/output electrode side. This makes it possible to prevent or reduce the risk of short circuits caused by migration (in particular, migration of Ag ions which are prone to migration).

Herein, whether a pore is a through pore can be determined by polishing a cross-section in the thickness direction of the module and observing a pore appearing on the surface of the cross-section with an electron microscope to find whether it is a through pore.

The state: “the pores in the insulating layer between the in-plane wiring and the input/output electrode are not through from the in-plane wiring side to the input/output electrode side” can be achieved by forming an insulating layer using a solder resist that contains a filler in an amount of 21 wt % or more and 31 wt % or less and a resin in an amount of 31 wt % or more and 41 wt % or less.

Preferably, the conductive filler in the rewiring conductors includes spherical particles that are physically in contact with each other to be electrically connected, and the rewiring conductors each include pores having an aspect ratio of 3.0 or lower. This makes it possible to further prevent or suppress degradation due to thermal cycling. The effect can be achieved probably because allowing the spherical particles of the filler to be in point contact with each other can further improve the flexibility of the rewiring conductors. Moreover, pores having a small aspect ratio in the rewiring conductors can be better prevented from becoming the starting points of cracks.

The pores in the rewiring conductors preferably have an aspect ratio of 3.0 or lower, more preferably 2.7 or lower, still more preferably 2.4 or lower. The lower limit is not limited, and it is preferably 1.2 or higher.

Herein, the aspect ratio of pores is calculated by the method below.

FIG. 3 is a schematic view of an example of pores in a rewiring conductor. A cross-section in the thickness direction of the module is polished. The sizes of pores appearing on the surface of the cross-section are measured with an electron microscope. The shortest width W and the longest width L of each pore are measured and subjected to calculation by the following calculation formula. The aspect ratios of at least 100 pores are measured, and the number average value is defined as an aspect ratio.

Aspect ratio=L/W

The state: “the conductive filler in the rewiring conductors includes spherical particles that are physically in contact with each other to be electrically connected, and the rewiring conductors each include pores having an aspect ratio of 3.0 or lower” can be achieved by, for example, forming a rewiring conductor using a conductive filler paste that contains a conductive filler including spherical particles in an amount of 84 wt % or more and 88 wt % or less, a solvent, and a resin.

In FIG. 2, the via 162 has a reverse tapered cross-sectional shape with a side farther from the input/output electrode 104 is longer than a side facing the input/output electrode 104, the input/output electrode 104 has a convex portion 104a in a region overlapping the via 162 in a plan view, and the periphery 104b of the convex portion is concave. As described above, preferably, the connecting conductor includes a via extending in the insulating layer in the thickness direction to directly contact the input/output electrode, the via has a reverse tapered cross-sectional shape with a side farther from the input/output electrode being longer than a side facing the input/output electrode, the input/output electrode has a convex portion in a region overlapping the via in a plan view, and the periphery of the convex portion is concave. This makes it possible to further prevent or suppress degradation due to thermal cycling. The effect can be achieved probably because a via having a reverse tapered shape can prevent or suppress peeling between the via and a rewiring conductor other than the via due to the stress from thermal expansion of the surrounding insulating layer. Moreover, the input/output electrode having a convex portion, which is directly beneath the via, can prevent or suppress void generation between solder and the input/output electrode to increase the bonding strength between the solder and the input/output electrode. Further, the concave at the periphery of the convex portion on the input/output electrode directly beneath the via functions like a wedge to further increase the bonding strength between the solder and the input/output electrode.

Herein, the shapes of vias and electrodes can be determined by polishing a cross-section in the thickness direction of the module and observing the vias and the electrodes appearing on the surface of the cross-section.

The rewiring conductors such as the in-plane wiring 164, the vias 162, and the input/output electrodes 104 may be made of different or the same materials and/or may have different or the same properties.

The average pore diameters of the rewiring conductors such as the in-plane wiring 164, the vias 162, and the input/output electrodes 104 may be the same or different from each other. Likewise, the numbers of pores (densities) of the rewiring conductors such as the in-plane wiring 164, the vias 162, and the input/output electrodes 104 may be the same or different from each other.

The electronic component module 100 is produced by the following method, for example.

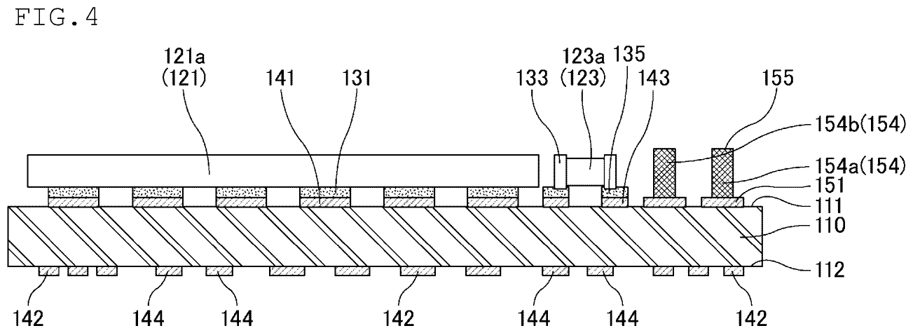

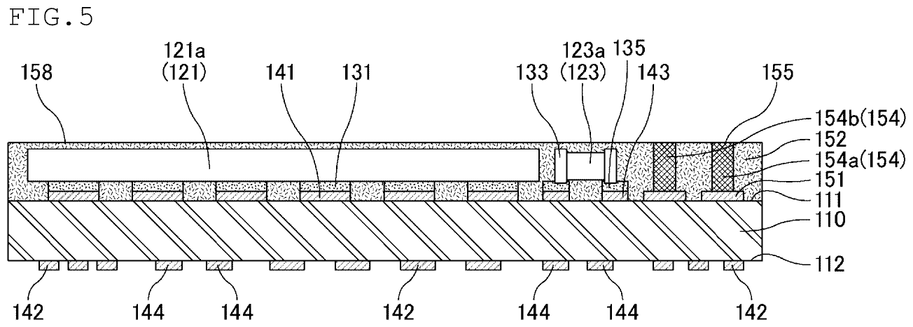

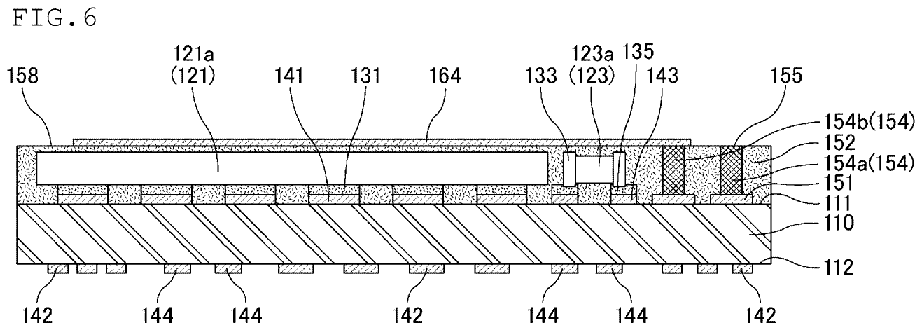

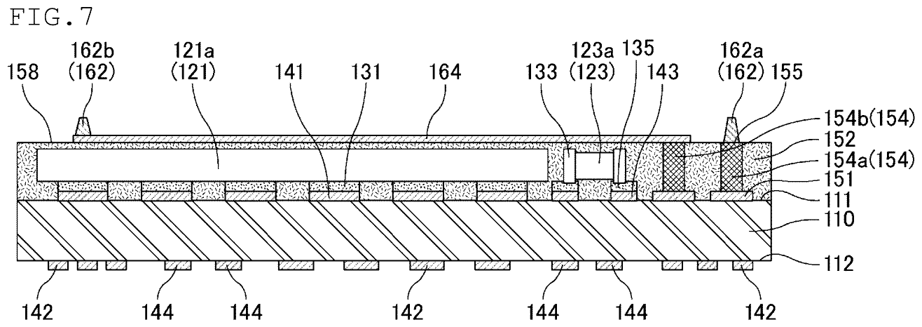

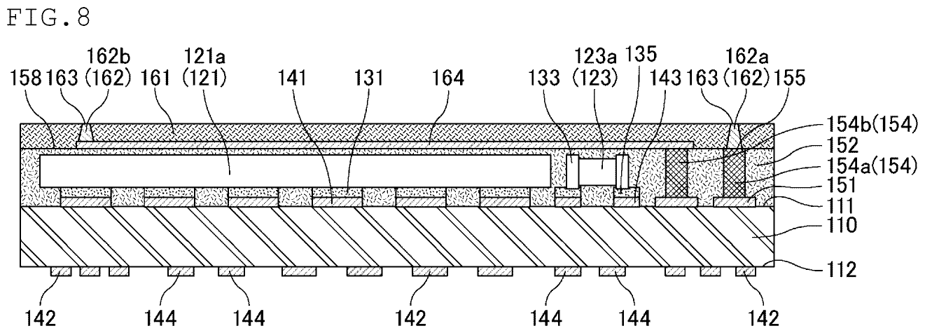

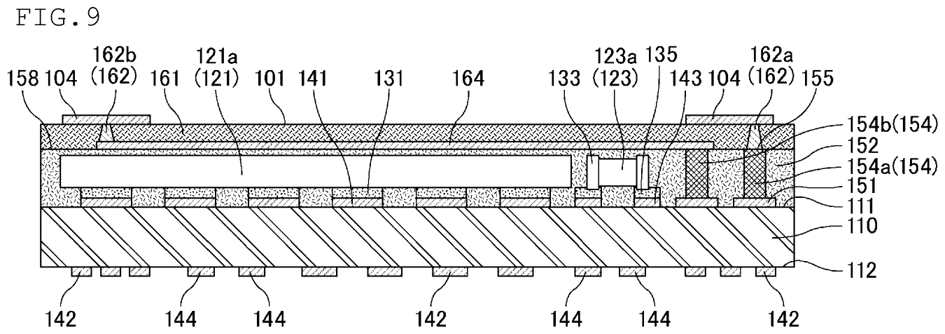

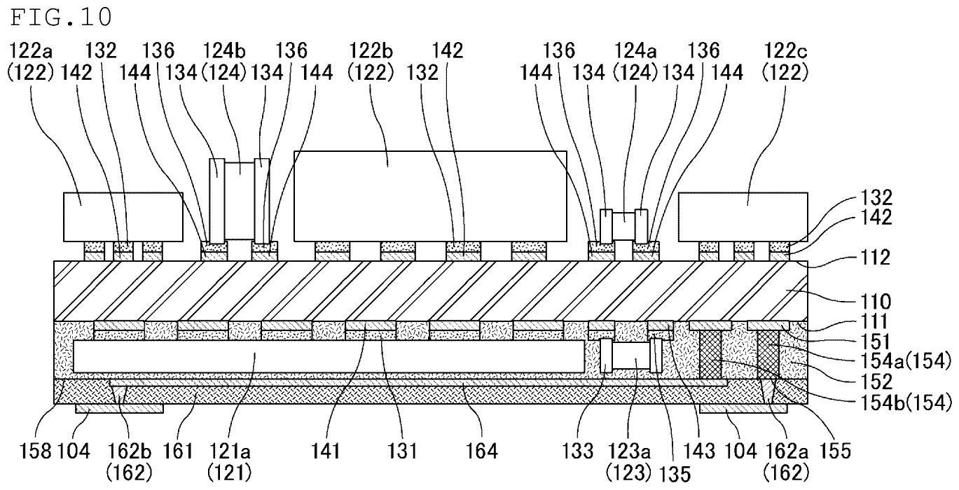

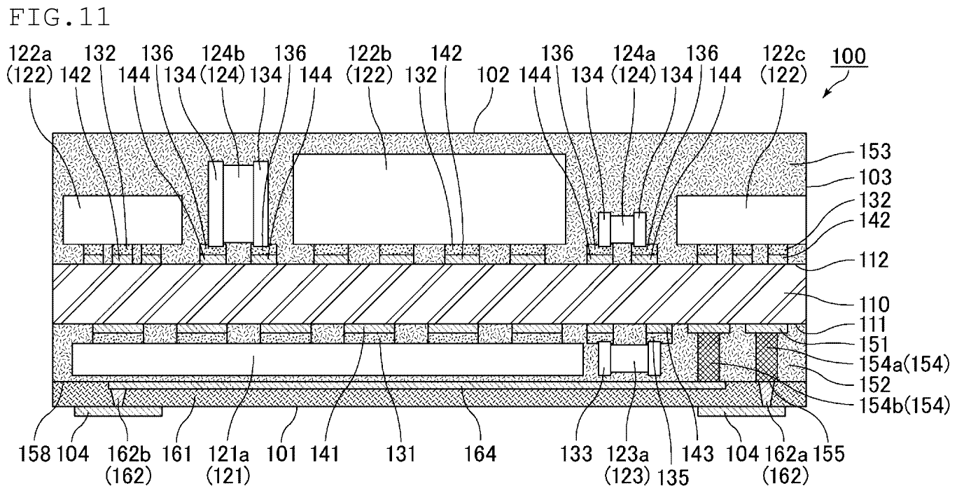

FIG. 4 to FIG. 11 are each a schematic cross-sectional view of an example of the electronic component module of the present disclosure (first embodiment) during production. FIG. 4 shows mounting of a first electronic component and a third electronic component. FIG. 5 shows first sealing with a resin. FIG. 6 shows forming of an in-plane wiring. FIG. 7 shows forming of a via. FIG. 8 shows forming of an insulating layer. FIG. 9 shows forming of an input/output electrode. FIG. 10 shows mounting of a second electronic component and a fourth electronic component. FIG. 11 shows second sealing with a resin.

Hereinafter, an assembly board including multiple LTCC substrates is described. For the sake of convenience, FIG. 4 to FIG. 11 each show a singulated LTCC substrate as an assembly board.

First, the first electronic component 121 including the multiple Cu pillar bumps 131 as external terminals and the third electronic component 123 are mounted and reflowed on a first main surface (which corresponds to the first main surface 111 of the LTCC substrate 110 shown in FIG. 4) of the assembly board including multiple LTCC substrates. In addition, Cu (copper) pins, for example, are formed as the columnar electrodes 154 on the electrodes for input/output 151.

Next, as shown in FIG. 5, the sealing resin layer 152 is formed on a first main surface 171 of an assembly board 170 such that it coats the first electronic component 121 and the third electronic component 123 and covers the side faces of the columnar electrodes 154. Each columnar electrode has an end surface 155 exposed from the sealing resin layer 152.

Specifically, for example, a semi-cured sealing resin sheet (e.g., a sheet made of a thermosetting resin such as epoxy resin) is placed on the first main surface 171, and the sealing resin is heated while being pressed with a plate for molding. Thus, the sealing resin is fluidized to fill in the space such as a gap between the first electronic component 121 and the assembly board 170, and then the sealing resin cures.

Next, as shown in FIG. 6, the in-plane wiring 164 is formed on a main surface 158 of the sealing resin layer 152. The in-plane wiring 164 is formed such that it covers an end surface 155 of the second columnar electrode 154b, thereby forming the in-plane wiring 164 connected to the second columnar electrode 154b.

Specifically, for example, a paste containing a conductive filler, a resin, and a solvent is printed by screen-printing on the main surface 158 of the sealing resin layer 152, and then the printed film of the paste is subjected to heat treatment to form the in-plane wiring 164 which is a dry film.

The conductive filler and the resin in the paste are as described above.

The solvent in the paste may be any solvent that can disperse the conductive filler and the resin and will volatilize in the heat treatment. Examples of the solvent include diethylene glycol monoethyl ether acetate.

The amount of the conductive filler in the paste relative to the amount of the paste as a whole is preferably 80 wt % or more and 95 wt % or less, more preferably 83 wt % or more and 92 wt % or less.

The amount of the resin in the paste relative to the amount of the paste as a whole is preferably 1 wt % or more and 10 wt % or less, more preferably 3 wt % or more and 8 wt % or less.

The amount of the solvent in the paste relative to the amount of the paste as a whole is preferably 4 wt % or more and 15 wt % or less, more preferably 6 wt % or more and 13 wt % or less.

The total amount of the conductive filler, the resin, and the solvent in the paste relative to the amount of the paste as a whole is preferably 80 wt % or more, more preferably 85 wt % or more, and may be 100 wt %.

Next, as shown in FIG. 7, vias 162 are formed on the end surface 155 of the first columnar electrode 154a and on the in-plane wiring 164, thereby forming a via 162a connected to the first columnar electrode 154a and a via 162b connected to the in-plane wiring 164.

Specifically, for example, a paste containing a conductive filler, a resin, and a solvent is printed by screen-printing on the end surface 155 of the first columnar electrode 154a and on the in-plane wiring 164, and then the printed films of the paste are subjected to heat treatment to form the vias 162 which are dry films.

The paste used to form vias may be the same as the paste used to form in-plane wirings.

Next, as shown in FIG. 8, the insulating layer 161 is formed on the main surface 158 of the sealing resin layer 152, thereby forming the insulating layer 161 that covers the in-plane wiring 164 and the like.

Specifically, for example, a paste containing a filler, a resin, and a solvent is printed by screen-printing on the main surface 158 of the sealing resin layer 152, and then the printed film of the paste is subjected to heat treatment to form the insulating layer 161.

End surfaces 163 of the vias 162 are exposed from the insulating layer 161.

The filler and the resin in the paste are as described above.

The solvent in the paste may be any solvent that can disperse the filler and the resin and will volatilize in the heat treatment. The solvent may be the same as the solvent in the paste used to form in-plane wirings.

The amount of the filler in the paste relative to the amount of the paste as a whole is preferably 10 wts or more and 30 wt % or less, more preferably 15 wt % or more and 25 wt % or less.

The amount of the resin in the paste relative to the amount of the paste as a whole is preferably 30 wt % or more and 50 wt % or less, more preferably 35 wt % or more and 45 wt % or less.

The amount of the solvent in the paste relative to the amount of the paste as a whole is preferably 30 wt % or more and 45 wt % or less, more preferably 33 wt % or more and 42 wt % or less.

The total amount of the filler, the resin, and the solvent in the paste relative to the amount of the paste as a whole is preferably 50 wt % or more, more preferably 53 wt % or more, and may be 100 wt %.

Next, as shown in FIG. 9, the input/output electrodes 104 are formed on the insulating layer 161. The input/output electrodes 104 cover the end surfaces 163 of the respective vias 162, thereby forming the input/output electrodes 104 connected to the respective vias 162.

Specifically, for example, a paste containing a conductive filler, a resin, and a solvent is printed by screen-printing on the insulating layer 161, and then the printed film of the paste is subjected to heat treatment to form the input/output electrodes 104 which are dry films.

The paste used to form input/output electrodes may be the same as the paste used to form in-plane wirings.

Next, as shown in FIG. 10, the second electronic components 122 including the multiple Cu pillar bumps 132 as external terminals and other electronic components such as the fourth electronic components 124 are mounted and reflowed on a second main surface 172 (which corresponds to the second main surface 112 of the LTCC substrate 110) of the assembly board 170.

Next, as shown in FIG. 11, the sealing resin layer 153 is formed such that it covers the second electronic components 122 and other electronic components.

The sealing resin layer 153 can be formed in the same manner as the sealing resin layer 152. In other words, for example, a semi-cured sealing resin sheet (e.g., a sheet made of a thermosetting resin such as epoxy resin) is placed on the second main surface 172, and the sealing resin is heated while being pressed with a plate for molding. Thus, the sealing resin is fluidized to fill in the space such as a gap between the second electronic components 122 and the second main surface 172, and then the sealing resin cures.

The sealing resins for the sealing resin layers 152 and 153 may contain a filler such as alumina, silica, silicon nitride, aluminum hydroxide, barium titanate, or titania.

The average particle size of the filler in each of the sealing resins for the sealing resin layers 152 and 153 may be, for example, 5 μm or more and 15 μm or less, 7 μm or more and 13 μm or less, or 9 μm or more and 11 μm or less, or may be 10 μm.

The sealing resins for the sealing resin layers 152 and 153 may each have a filler content of, for example, 70 wt % or more and 98 wt % or less relative to the amount of the sealing resin as a whole.

Next, the assembly board 170 is cut at predetermined positions by a dicer or the like for singulation, whereby each LTCC substrate 110 is cut out.

Thus, the electronic component module 100 according to the first embodiment is produced.

The module of the present disclosure has a feature that the pores in the rewiring conductor have a smaller average diameter than the pores in the insulating layer. Modules having this feature can be produced by a method including forming a rewiring conductor using a paste that contains a conductive filler having an average particle size of 0.1 μm or more and 1.0 μm or less, a resin, and a solvent and forming an insulating layer using a paste that contains a filler having an average particle size of more than 1.0 μm and 10.0 μm or less, a resin, and a solvent.

The method for forming the in-plane wiring 164, the method for forming the vias 162, and the method for forming the input/output electrodes 104 described above are examples of “forming a rewiring conductor” in the method for producing the module of the present disclosure.

The method for forming the insulating layer 161 described above is an example of “forming an insulating layer” in the method for producing the module of the present disclosure.

Pores in the rewiring conductors are formed upon volatilization of the solvent in the paste used to form the rewiring conductors. The pore diameter greatly depends on the average particle size of the filler in the paste. The smaller the average particle size of the filler is, the smaller the pore diameter becomes. This may be because, since a solvent is present in the gap between the particles of the filler, the filler having a small particle size has a small space to which the solvent can enter around the particles, leading to a small pore diameter. The pore diameter also depends on the filler content and the solvent content of the paste. A rewiring conductor having a desired average pore diameter can be formed by screen printing a paste prepared while appropriately controlling the contents.

Pores in the insulating layer can also be controlled by the above-described technique.

Although the module according to the first embodiment described above includes two columnar electrodes, the number of columnar electrodes in the module of the present disclosure is not limited.

Although the module according to the first embodiment described above includes one in-plane wiring, the number of in-plane wirings in the module of the present disclosure is not limited.

Although the module according to the first embodiment described above includes two vias, the number of vias in the module of the present disclosure is not limited.

Although the module according to the first embodiment described above includes two input/output electrodes, the number of input/output electrodes in the module of the present disclosure is not limited.

Although the module according to the first embodiment described above includes one rewiring layer, the number of rewiring layers in the module of the present disclosure is not limited. Both the main surfaces of the sealed body each may have a rewiring layer thereon.

### Second Embodiment

The present embodiment is different from the first embodiment in that the connecting conductor includes two in-plane wiring layers extending in the insulating layer in the surface direction.

In the present disclosure, the pores in the insulating layer between the multiple in-plane wiring layers may be through or not through, preferably not through, between the multiple in-plane wiring layers.

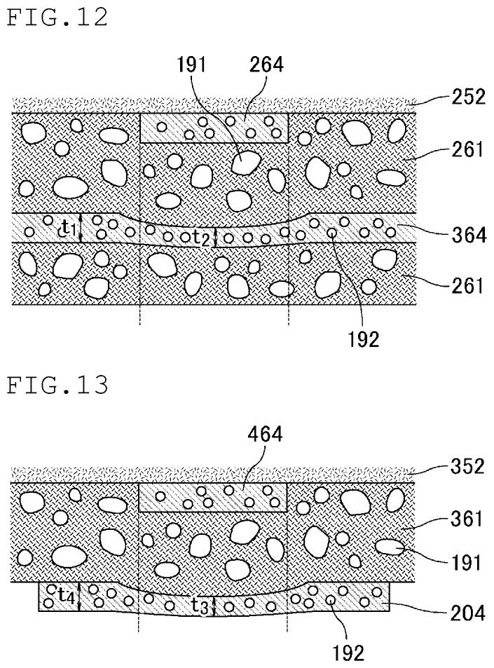

FIG. 12 is a schematic cross-sectional view of an example of a rewiring layer in the present disclosure (second embodiment).

In FIG. 12, two in-plane wiring layers are present, specifically, an in-plane wiring 264 that is formed on a sealing resin layer 252 and extends into the page and an in-plane wiring 364 that is in the insulating layer 261 and extends laterally in the drawing. The insulating layer 261 covers the sealing resin layer 252 excluding the area where the in-plane wiring 264 is formed. Moreover, the insulating layer 261 covers the entire surface of the in-plane wiring 364.

Pores 191 in the insulating layer 261 between the two in-plane wiring layers (the in-plane wiring 264 and the in-plane wiring 364) are not through between the two in-plane wiring layers. As described above, preferably, the connecting conductor includes multiple in-plane wiring layers extending in the insulating layer in the surface direction, and the pores in the insulating layer between the multiple in-plane wiring layers are not through between the multiple in-plane wiring layers. This makes it possible to prevent or reduce the risk of short circuits caused by migration (in particular, migration of Ag ions which are prone to migration).

The state: “the pores in the insulating layer between the multiple in-plane wiring layers are not through between the multiple in-plane wiring layers” may be achieved by the above-described technique or similar techniques to achieve the state: “the pores in the insulating layer between the in-plane wiring and the input/output electrode are not through from the in-plane wiring side to the input/output electrode side”.

In the present disclosure, in the case where the connecting conductor includes multiple in-plane wiring layers extending in the insulating layer in the surface direction, an in-plane wiring farther from the sealed body in an overlapping region where the multiple in-plane wiring layers overlap with each other may have a thickness that is the same as or different from that in a region adjacent to the overlapping region. Preferably, the thickness of the in-plane wiring farther from the sealed body in an overlapping region where the multiple in-plane wiring layers overlap with each other is smaller than that in a region adjacent to the overlapping region.

In FIG. 12, with regard to the thickness of the in-plane wiring 364 at a position farther from the sealed body 180 (sealing resin layer 252), the thickness (thickness indicated by a double-headed arrow t2) of the in-plane wiring 364 in an overlapping region (region between two dashed lines in FIG. 12) where two in-plane wiring layers overlap with each other is smaller than the thickness (thickness indicated by a double-headed arrow t1) of the in-plane wiring 364 in a region adjacent to the overlapping region. As described above, the connecting conductor includes multiple in-plane wiring layers extending in the insulating layer in the surface direction, and an in-plane wiring farther from the sealed body has a thickness that is smaller in an overlapping region where the multiple in-plane wiring layers overlap with each other than that in a region adjacent to the overlapping region. This makes it possible to reduce the variation in the thicknesses of all the rewiring layers, so that concentration of thermal stress on electrodes can be reduced.

The above-described relationship regarding the thickness can be achieved by forming in-plane wirings by screen printing using a printing plate having an open volume of 9 cm³/m² or more.

Herein, the thicknesses of in-plane wirings can be determined by polishing a cross-section in the thickness direction of the module and observing the in-plane wirings appearing on the surface of the cross-section.

### Third Embodiment

The present embodiment is different from the first embodiment in the structure of the input/output electrode.

In the present disclosure, the connecting conductor includes an in-plane wiring extending in an insulating layer in the surface direction, and an input/output electrode in an overlapping region where the in-plane wiring overlaps the input/output electrode in a plan view may have a thickness that is the same as or different from that in a region adjacent to the overlapping region. Preferably, the input/output electrode has a thickness that is smaller in the overlapping region where the in-plane wiring overlaps the input/output electrode in a plan view than that in a region adjacent to the overlapping region.

FIG. 13 is a schematic cross-sectional view of an example of a rewiring layer in the present disclosure (third embodiment).

In FIG. 13, an in-plane wiring 464 extending into the page is formed on a sealing resin layer 352. An insulating layer 361 covers the sealing resin layer 352 excluding the area where the in-plane wiring 464 is formed. Further, an input/output electrode 204 is formed on a surface of the insulating layer 361 on a side opposite to the side facing the sealing resin layer 352. The in-plane wiring 464 overlaps the input/output electrode 204 in a plan view.

In FIG. 13, the thickness (thickness indicated by a double-headed arrow t3) of the input/output electrode 204 in an overlapping region (region between two dashed lines in FIG. 13) where the in-plane wiring 464 overlaps the input/output electrode 204 in a plan view is smaller than the thickness (thickness indicated by a double-headed arrow t4) of the input/output electrode 204 in a region adjacent to the overlapping region. As described above, the connecting conductor includes an in-plane wiring extending in the insulating layer in the surface direction, and the input/output electrode has a thickness that is smaller in an overlapping region where the in-plane wiring overlaps the input/output electrode in a plan view than that in a region adjacent to the overlapping region. This makes it possible to reduce the variation in the thicknesses of all the rewiring layers, so that concentration of thermal stress on electrodes can be reduced.

The above-described relationship regarding the thickness can be achieved by forming in-plane wirings and/or input/output electrodes by screen printing using a printing plate having an open volume of 9 cm³/m² or more.

Herein, the thicknesses of input/output electrodes can be determined by polishing a cross-section in the thickness direction of the module and observing the input/output electrodes appearing on the surface of the cross-section.

The above embodiments were described with reference to the case where the LTCC substrate, which is a type of an inorganic material substrate, is used as a circuit board, but the circuit board of the module of the present disclosure is not limited as long as it is a printed wiring board (preferably, a multilayer board).

The inorganic material substrate is not limited as long as it is a circuit board (preferably, a multilayer board) containing an inorganic material (preferably, ceramic) as an insulating material.

The above embodiments were described with reference to the case where the first electronic component 121 including a mounting surface provided with the multiple Cu pillar bumps 131 and the second electronic component 122 including a mounting surface provided with the multiple Cu pillar bumps 132 are mounted. Yet, the first electronic component and the second electronic component of the electronic component module of the present disclosure are not limited. They may be electronic components each including a mounting surface provided with multiple external terminals. More specifically, they may be, for example, electronic components (preferably, ICs) with land grid array (LGA) structures or electronic components (preferably, ICs) with ball grid array (BGA) structures.

In the case of electronic components with LGA structures, each external terminal (land) may be connected to the circuit board with solder.

In either case, usually, the multiple external terminals include three or more external terminals that are arrayed regularly at an equal pitch only on the mounting surface. For example, the external terminals may be arrayed, for example, in an annular shape such as a rectangular shape on the mounting surface or may be arrayed in a grid (matrix) shape on the mounting surface.

Herein, the following is disclosed.

<1> A module, including: a sealed body including a circuit board and an electronic component each sealed with a sealing resin, wherein a conductor is exposed from a part of a surface of the sealed body; and a rewiring layer disposed on the surface of the sealed body and including an insulating layer and a rewiring conductor connected to the conductor, wherein the rewiring conductor includes: a connecting conductor disposed in the insulating layer and connected to the conductor; and an input/output electrode disposed on a surface of the insulating layer on a side opposite to a side facing the sealed body and connected to the connecting conductor, and the rewiring conductor and the insulating layer include first pores and second pores, respectively, each of the first pores having a smaller average diameter than each of the second pores.

<2> The module described in the above <1>, wherein the rewiring conductor contains a conductive filler and a resin.

<3> The module described in the above <2>, wherein the conductive filler includes spherical particles being physically in contact with each other to be electrically connected, and each of the first pores has an aspect ratio of 3.0 or lower.

<4> The module described in the above <2> or <3>, wherein the conductive filler has an average particle size of 0.1 μm or more and 1.0 μm or less.

<5> The module described in any one of the above <1> to <4>, wherein the connecting conductor includes an in-plane wiring extending in the insulating layer in a surface direction, and the second pores in a portion of the insulating layer between the in-plane wiring and the input/output electrode do not penetrate entirely through the insulating layer from the in-plane wiring to the input/output electrode.

<6> The module described in any one of the above <1> to <5>, wherein the connecting conductor includes multiple in-plane wiring layers extending in the insulating layer in a surface direction, and the second pores in a portion of the insulating layer between the multiple in-plane wiring layers do not penetrate entirely through the insulating layer from one of the multiple in-plane wiring layers to another one of the multiple in-plane wiring layers.

<7> The module described in any one of the above <1> to <6>, wherein the connecting conductor includes a via extending in the insulating layer in the thickness direction to directly contact the input/output electrode, the via has a reverse tapered cross-sectional shape with a side farther from the input/output electrode being longer than a side facing the input/output electrode, the input/output electrode has a convex portion in a region overlapping the via in a plan view, and a periphery of the convex portion is concaved.

<8> The module described in any one of the above <1> to <7>, wherein the connecting conductor includes an in-plane wiring extending in the insulating layer in a surface direction, and the input/output electrode has a thickness that is smaller in an overlapping region where the in-plane wiring overlaps the input/output electrode than that in a region adjacent to the overlapping region in a plan view.

<9> The module described in any one of the above <1> to <8>, wherein the connecting conductor includes multiple in-plane wiring layers extending in the insulating layer in a surface direction, and a thickness of a portion of an in-plane wiring farther from the sealed body in an overlapping region where the multiple in-plane wiring layers overlap with each other is less than a thickness of a portion of the in-plane wiring in a region adjacent to the overlapping region.

<10> A method for producing the module described in any one of the above <1> to <9>, including: forming the rewiring conductor by screen printing using a first paste containing a conductive filler having an average particle size of 0.1 μm or more and 1.0 μm or less, a resin, and a solvent; and forming the insulating layer by screen printing using a second paste containing a filler having an average particle size of more than 1.0 μm and 10 μm or less, a resin, and a solvent.
100 electronic component module
101 mounting surface of electronic component module
102 top surface of electronic component module
103 side surface of electronic component module
104, 204 input/output electrode
104a convex portion
104b periphery of convex portion
110 low-temperature sintered ceramic substrate
111 first main surface of low-temperature sintered ceramic substrate
112 second main surface of low-temperature sintered ceramic substrate
121 first electronic component
121a SOI
122 second electronic component
122a HBT IC
122b SAW filter
122c GaAs IC
123 third electronic component
123a, 124a chip capacitor
124 fourth electronic component
124b chip inductor
131, 132 Cu pillar bump
133, 134 external electrode
135, 136 solder
141 first electrode
142 second electrode
143 third electrode
144 fourth electrode
151 electrode for input/output
152, 153, 252, 352 sealing resin layer
154 columnar electrode
154a first columnar electrode
154b second columnar electrode
155 end surface of columnar electrode
158 main surface of sealing resin layer
161, 261, 361 insulating layer
162, 162a, 162b via
163 end surface of via
164, 264, 364, 464 in-plane wiring
170 assembly board
171 first main surface of assembly board
172 second main surface of assembly board
180 sealed body
190 rewiring layer
191 pores in insulating layer
192 pores in rewiring conductor

1. A module, comprising:
a sealed body comprising a circuit board and an electronic component each sealed with a sealing resin, wherein a conductor is exposed from a part of a surface of the sealed body; and
a rewiring layer disposed on the surface of the sealed body and including an insulating layer and a rewiring conductor connected to the conductor,
wherein the rewiring conductor includes:
a connecting conductor disposed in the insulating layer and connected to the conductor; and
an input/output electrode disposed on a surface of the insulating layer on a side opposite to a side facing the sealed body and connected to the connecting conductor, and
the rewiring conductor and the insulating layer include first pores and second pores, respectively, each of the first pores having a smaller average diameter than each of the second pores.

2. The module according to claim 1,
wherein the rewiring conductor contains a conductive filler and a resin.

3. The module according to claim 2,
wherein the conductive filler includes spherical particles being physically in contact with each other to be electrically connected, and
each of the first pores has an aspect ratio of 3.0 or lower.

4. The module according to claim 2,
wherein the conductive filler has an average particle size of 0.1 μm or more and 1.0 μm or less.

5. The module according to claim 1,
wherein the connecting conductor includes an in-plane wiring extending in the insulating layer in a surface direction, and
the second pores in a portion of the insulating layer between the in-plane wiring and the input/output electrode do not penetrate entirely through the insulating layer from the in-plane wiring to the input/output electrode.

6. The module according to claim 1,
wherein the connecting conductor includes multiple in-plane wiring layers extending in the insulating layer in a surface direction, and
the second pores in a portion of the insulating layer between the multiple in-plane wiring layers do not penetrate entirely through the insulating layer from one of the multiple in-plane wiring layers to another one of the multiple in-plane wiring layers.

7. The module according to claim 1,
wherein the connecting conductor includes a via extending in the insulating layer in the thickness direction to directly contact the input/output electrode,
the via has a reverse tapered cross-sectional shape with a side farther from the input/output electrode being longer than a side facing the input/output electrode,
the input/output electrode has a convex portion in a region overlapping the via in a plan view, and
a periphery of the convex portion is concaved.

8. The module according to claim 1,
wherein the connecting conductor includes an in-plane wiring extending in the insulating layer in a surface direction, and
the input/output electrode has a thickness that is smaller in an overlapping region where the in-plane wiring overlaps the input/output electrode than that in a region adjacent to the overlapping region in a plan view.

9. The module according to claim 1,
wherein the connecting conductor includes multiple in-plane wiring layers extending in the insulating layer in a surface direction, and
a thickness of a portion of an in-plane wiring farther from the sealed body in an overlapping region where the multiple in-plane wiring layers overlap with each other is less than a thickness of a portion of the in-plane wiring in a region adjacent to the overlapping region.

10. A method for producing the module according to claim 1, comprising:
forming the rewiring conductor by screen printing using a first paste containing a conductive filler having an average particle size of 0.1 μm or more and 1.0 μm or less, a resin, and a solvent; and
forming the insulating layer by screen printing using a second paste containing a filler having an average particle size of more than 1.0 μm and 10.0 μm or less, a resin, and a solvent.

11. The module according to claim 3,
wherein the conductive filler has an average particle size of 0.1 μm or more and 1.0 μm or less.

12. The module according to claim 2,
wherein the connecting conductor includes an in-plane wiring extending in the insulating layer in a surface direction, and
the second pores in a portion of the insulating layer between the in-plane wiring and the input/output electrode do not penetrate entirely through the insulating layer from the in-plane wiring to the input/output electrode.

13. The module according to claim 3,
wherein the connecting conductor includes an in-plane wiring extending in the insulating layer in a surface direction, and
the second pores in a portion of the insulating layer between the in-plane wiring and the input/output electrode do not penetrate entirely through the insulating layer from the in-plane wiring to the input/output electrode.

14. The module according to claim 4,
wherein the connecting conductor includes an in-plane wiring extending in the insulating layer in a surface direction, and
the second pores in a portion of the insulating layer between the in-plane wiring and the input/output electrode do not penetrate entirely through the insulating layer from the in-plane wiring to the input/output electrode.

15. The module according to claim 2,
wherein the connecting conductor includes multiple in-plane wiring layers extending in the insulating layer in a surface direction, and
the second pores in a portion of the insulating layer between the multiple in-plane wiring layers do not penetrate entirely through the insulating layer from one of the multiple in-plane wiring layers to another one of the multiple in-plane wiring layers.

16. The module according to claim 3,
wherein the connecting conductor includes multiple in-plane wiring layers extending in the insulating layer in a surface direction, and
the second pores in a portion of the insulating layer between the multiple in-plane wiring layers do not penetrate entirely through the insulating layer from one of the multiple in-plane wiring layers to another one of the multiple in-plane wiring layers.

17. The module according to claim 4,
wherein the connecting conductor includes multiple in-plane wiring layers extending in the insulating layer in a surface direction, and
the second pores in a portion of the insulating layer between the multiple in-plane wiring layers do not penetrate entirely through the insulating layer from one of the multiple in-plane wiring layers to another one of the multiple in-plane wiring layers.

18. The module according to claim 5,
wherein the connecting conductor includes multiple in-plane wiring layers extending in the insulating layer in a surface direction, and
the second pores in a portion of the insulating layer between the multiple in-plane wiring layers do not penetrate entirely through the insulating layer from one of the multiple in-plane wiring layers to another one of the multiple in-plane wiring layers.

19. The module according to claim 2,
wherein the connecting conductor includes a via extending in the insulating layer in the thickness direction to directly contact the input/output electrode,
the via has a reverse tapered cross-sectional shape with a side farther from the input/output electrode being longer than a side facing the input/output electrode,
the input/output electrode has a convex portion in a region overlapping the via in a plan view, and
a periphery of the convex portion is concaved.

20. The module according to claim 3,
wherein the connecting conductor includes a via extending in the insulating layer in the thickness direction to directly contact the input/output electrode,
the via has a reverse tapered cross-sectional shape with a side farther from the input/output electrode being longer than a side facing the input/output electrode,
the input/output electrode has a convex portion in a region overlapping the via in a plan view, and
a periphery of the convex portion is concaved.
